(19) United States
(12) Patent Application Publication
(10) Pub. No.: US 2026/0018214 A1
(43) Pub. Date: Jan. 15, 2026

(54) MEMORY SYSTEM AND METHOD

(71) Applicant: Kioxia Corporation, Tokyo (JP)

(72) Inventor: Ryo YAMAKI, Yokohama (JP)

(21) Appl. No.: 19/063,549

(22) Filed: Feb. 26, 2025

(30) Foreign Application Priority Data
Jul. 9, 2024 (JP) 2024-110027

(51) Int. Cl. G11C 16/26; G06F 12/02; G11C 16/04

(52) U.S. Cl. CPC G11C 16/26; G06F 12/0246; G11C 16/0483

(57) ABSTRACT

A memory controller reads data from a first storage area of each of N memory cell groups based on changing a set value of a first read level in a change pattern defined by each different row of a first design matrix. The memory controller calculates a plurality of first coefficients of a first model formula based on the number of error bits in the data read from the first storage area of each of the N memory cell groups and a first model matrix. The memory controller calculates a correction amount of the set value of the first read level based on calculated values of the plurality of first coefficients and the first model formula. The memory controller updates the set value of the first read level based on the correction amount.

### CROSS-REFERENCE TO RELATED APPLICATIONS

This application is based upon and claims the benefit of priority from Japanese Patent Application No. 2024-110027, filed Jul. 9, 2024, the entire contents of which are incorporated herein by reference.

### FIELD

Embodiments described herein relate generally to a memory system and a method.

### BACKGROUND

In the related art, a memory system having a memory cell transistor is widely known. In such a memory system, in a read operation, data stored in the memory cell transistor is determined based on a comparison between a threshold voltage of the memory cell transistor and a read level.

The threshold voltage of the memory cell transistor may change due to various factors. Therefore, the memory system is configured to be able to correct the read level value.

### DESCRIPTION OF THE DRAWINGS

FIG. 1 is a diagram illustrating a configuration example of a memory system according to a first embodiment.

FIG. 2 is a diagram illustrating a configuration example of a memory chip according to the first embodiment.

FIG. 3 is a diagram illustrating a circuit configuration of a block according to the first embodiment.

FIG. 4 is a diagram for illustrating an example of data coding according to the first embodiment.

FIG. 5 is a diagram illustrating another example of the threshold voltage that may be taken by a memory cell according to the first embodiment.

FIG. 6 is a diagram for illustrating an example of a sequential read method according to the first embodiment.

FIG. 7 is a diagram illustrating an example of a relationship between an FBC and a read level value due to one read level according to the first embodiment.

FIG. 8 is a diagram illustrating a model formula of the first embodiment representing the FBC generated by the read operation for the lower page.

FIG. 9 is a diagram illustrating an example of a configuration of a correction unit for a read level correction operation for a lower page of the first embodiment.

FIG. 10 is a diagram illustrating an example of a design matrix D₁ and a model matrix X₁ related to the read level correction operation for the lower page of the first embodiment.

FIG. 11 is a diagram illustrating an example of a configuration of a correction unit for the read level correction operation for a middle page of the first embodiment.

FIG. 12 is a diagram illustrating a model formula of the first embodiment representing the FBC generated by a read operation for the middle page.

FIG. 13 is a diagram illustrating an example of a design matrix Dₘ and a model matrix Xₘ related to a read level correction operation for a middle page of a second embodiment.

FIG. 14 is a diagram illustrating an example of a configuration of a correction unit for a read level correction operation for an upper page of the first embodiment.

FIG. 15 is a diagram illustrating an example of data stored in a RAM provided in the memory system according to the first embodiment.

FIG. 16 is a schematic diagram for illustrating a data flow in the read level correction operation according to the first embodiment.

FIG. 17 is a flowchart illustrating an example of an operation of the memory system according to the first embodiment.

### DETAILED DESCRIPTION

Embodiments provide a memory system and a method capable of suitably correcting a read level value.

In general, according to one embodiment, a memory system includes a non-volatile first memory including a plurality of word lines and a plurality of memory cell groups, each of the plurality of memory cell groups connected to a corresponding one of the plurality of word lines, including a first storage area from which data is read using a first read level, and a second storage area from which data is read using a second read level; a second memory configured to store first information with a set value of the first read level being recorded, second information with a first design matrix having N rows that defines a change pattern of the first read level being recorded, and third information with a first model matrix being recorded, the first model matrix having N rows and corresponding to the first design matrix and a first model formula, and the first model formula having the first read level as an explanatory variable, the number of error bits as an objective variable, a position dependent term that is a term that depends on a position in N of the memory cell groups, and a plurality of first coefficients, wherein N is an integer equal to or greater than 2; and a memory controller configured to read data from the first storage area of each of the N memory cell groups based on changing the set value of the first read level in the change pattern defined by each different row of the first design matrix; calculate the plurality of first coefficients based on the number of error bits in the data read from the first storage area of each of the N memory cell groups and the first model matrix; calculate a correction amount of the set value of the first read level for reducing the number of error bits generated when performing a read operation for the first storage area of the N memory cell groups based on calculated values of the plurality of first coefficients and the first model formula; and update the set value of the first read level recorded in the first information based on the correction amount.

The memory system and the method according to the embodiment will be described in detail below with reference to the accompanying drawings. The present disclosure is not limited to the embodiments.

### First Embodiment

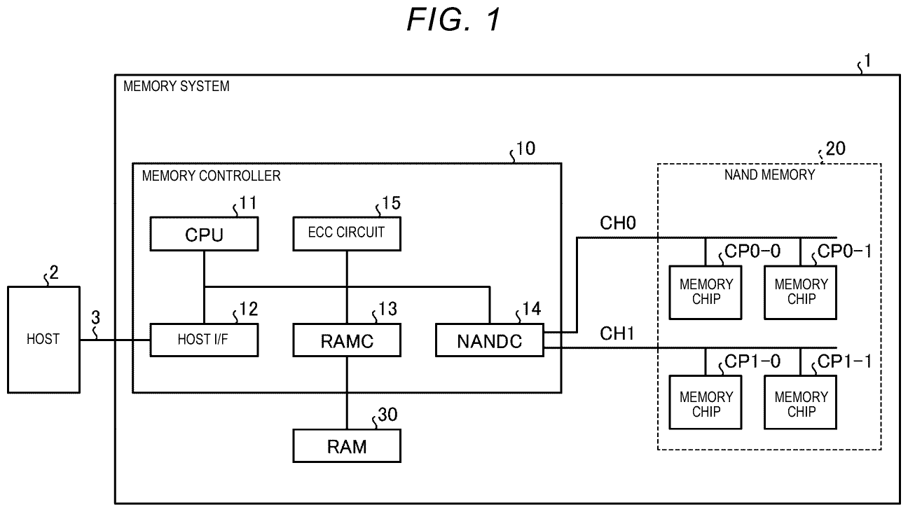

FIG. 1 is a diagram illustrating a configuration example of the memory system of a first embodiment. As illustrated in FIG. 1, a memory system 1 can be connected to a host 2. The host 2 is, for example, a server, a personal computer, a mobile information processing device, or the like. The memory system 1 functions as an external storage device of the host 2. The host 2 can issue a command to the memory system 1. The command for the memory system 1 includes a read command and a write command.

The memory system 1 includes a memory controller 10, a NAND flash memory (NAND memory) 20, and a random access memory (RAM) 30. The NAND memory 20 includes one or more memory chips CP.

Each memory chip CP includes a plurality of memory cell transistors and can store data in a non-volatile manner. Each memory chip CP is connected to the memory controller 10 by a channel CH.

Here, as an example, the NAND memory 20 includes four memory chips CP0-0, CP0-1, CP1-0, and CP1-1. The memory system 1 includes two channels CH0 and CH1. The memory chip CP0-0 and the memory chip CP0-1 are connected to the memory controller 10 by the channel CH0. The memory chip CP1-0 and the memory chip CP1-1 are connected to the memory controller 10 by the channel CH1.

The RAM 30 includes, for example, a dynamic random access memory (DRAM), a static random access memory (SRAM), or a combination thereof. The function performed by the RAM 30 may be implemented by any other type of memory capable of operating at a higher speed than the NAND memory 20. The function performed by the RAM 30 may be implemented by two or more types of memories.

The memory controller 10 includes a central processing unit (CPU) 11, a host interface (host I/F) 12, a random access memory controller (RAMC) 13, a NAND memory controller (NANDC) 14, and an error correction code circuit (ECC circuit) 15.

The memory controller 10 may be configured as, for example, a system-on-a-chip (SoC). The memory controller 10 may be configured with a plurality of chips. The memory controller 10 may be provided with a field-programmable gate array (FPGA) or an application specific integrated circuit (ASIC) instead of or in addition to the CPU 11. That is, the memory controller 10 may be configured with software, hardware, or a combination thereof. The RAM 30 may be disposed in the memory controller 10.

The host interface 12 is connected to the host 2 via a bus that complies with, for example, the serial advanced technology attachment (SATA) standard, the serial attached SCSI (SAS) standard, or the peripheral components interconnect (PCI) Express™ standard. The host interface 12 is a circuit that controls communication between the memory controller 10 and the host 2.

The NANDC 14 is a circuit that is connected to each memory chip CP via any of the channels CH and controls communication between the memory controller 10 and each memory chip CP.

The CPU 11 controls the operation of the memory controller 10.

The RAMC 13 is connected to the RAM 30. The RAMC 13 is a circuit that controls communication between the memory controller 10 and the RAM 30.

The ECC circuit 15 uses an error correction code to detect error bits and correct the detected error bits. The detection of the error bit and the correction of the detected error bit are simply referred to as error correction.

Further, the ECC circuit 15 can output the number of error bits detected when the error bits are detected. The number of error bits detected is referred to as a fail bit count (FBC). The ECC circuit 15 calculates the FBC based on a comparison between data before error correction and data after error correction, and outputs the calculated FBC.

The FBC may be calculated by another circuit (for example, the CPU 11). Further, a position where the ECC circuit 15 is provided is not limited to outside the NANDC 14. The ECC circuit 15 may be provided in the NANDC 14.

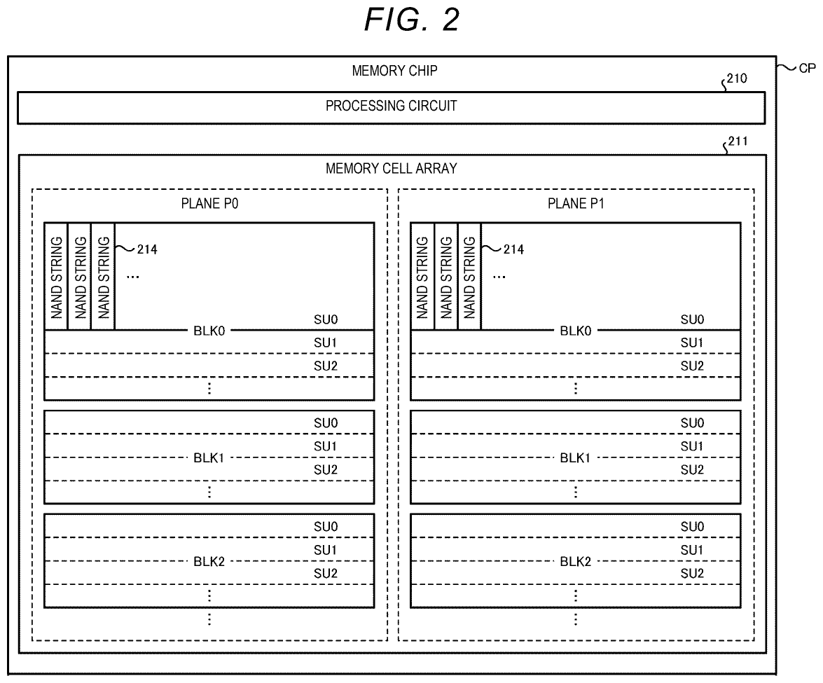

FIG. 2 is a diagram illustrating a configuration example of the memory chip CP according to the first embodiment. The memory chip CP includes a processing circuit 210 and a memory cell array 211 as illustrated in the drawing.

The memory cell array 211 is divided into a plurality of subarrays each belonging to a different plane P. Here, the memory cell array 211 is divided into a subarray belonging to a plane P0 and a subarray belonging to a plane P1. Each subarray includes a plurality of blocks BLK (BLK0, BLK1, . . . ) each of which is a set of a plurality of non-volatile memory cell transistors. Each block BLK includes a plurality of string units SU (SU0, SU1, . . . ) each of which is a set of memory cell transistors associated with word lines and bit lines. Each string unit SU includes a plurality of NAND strings 214 with which the memory cell transistors are connected in series. The number of NAND strings 214 in the string unit SU is optional. The number of divisions of the memory cell array 211 is not limited to 2. The memory cell array 211 may not necessarily be divided into a plurality of subarrays.

The processing circuit 210 includes, for example, a row decoder, a column decoder, a sense amplifier, a latch circuit, and a voltage generation circuit. The processing circuit 210 executes a program operation, a sense operation, and an erase operation for each subarray of each plane P in response to an instruction from the memory controller 10.

The program operation is an operation of writing data to the memory cell array 211. The sense operation is an operation of reading data from the memory cell array 211.

A series of operations in which the memory controller 10 writes data to the memory chip CP will be referred to as a write operation. The write operation is configured with a data-in operation in which the memory controller 10 transfers data to the memory chip CP and a program operation in which the processing circuit 210 writes the data received by the data-in operation to the memory cell array 211.

A series of operations in which the memory controller 10 reads data from the memory chip CP is referred to as a read operation. The read operation is configured with a sense operation in which the processing circuit 210 reads data from the memory cell array 211 and a data output operation in which the memory controller 10 acquires data read by the sense operation from the memory chip CP.

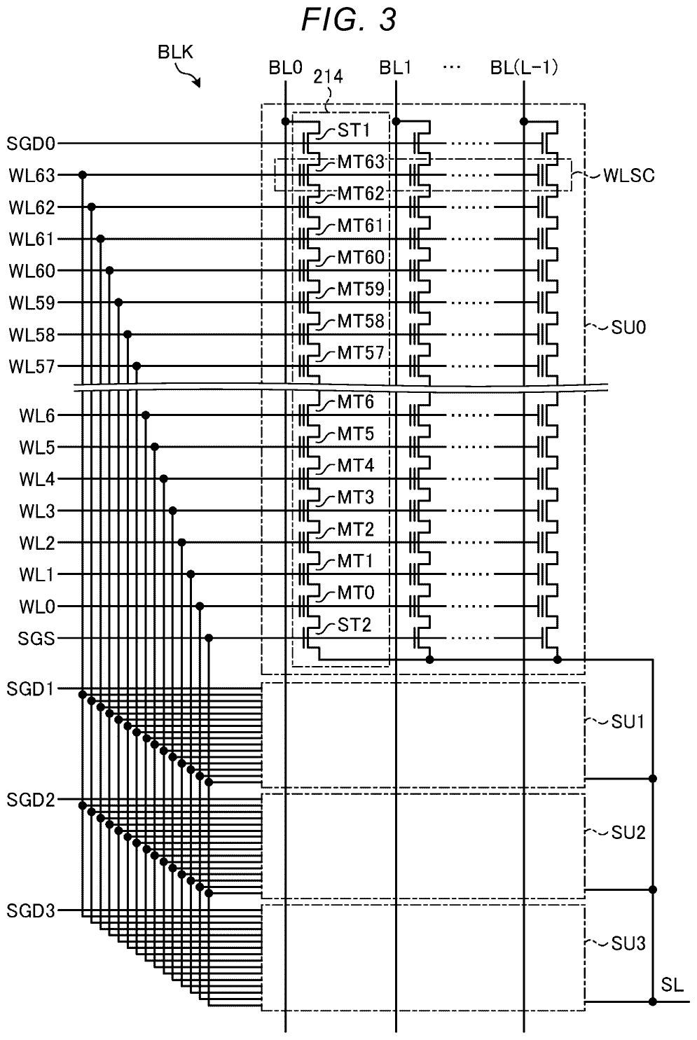

FIG. 3 is a diagram illustrating a circuit configuration of the block BLK according to the first embodiment. Each block BLK has the same configuration. The block BLK has, for example, four string units SU0 to SU3. Each string unit SU includes a plurality of NAND strings 214.

Each NAND string 214 includes, for example, 64 memory cell transistors MT (MT0 to MT63), and select transistors ST1 and ST2. The memory cell transistor MT includes a control gate and a charge storage layer, and stores data in a non-volatile manner. Then, the 64 memory cell transistors MT (MT0 to MT63) are connected in series between the source of the select transistor ST1 and the drain of the select transistor ST2. The memory cell transistor MT may be the MONOS type using an insulating film for a charge storage layer, or may be the FG type using a conductive film for the charge storage layer. Furthermore, the number of memory cell transistors MT in the NAND string 214 is not limited to 64.

The gate of the select transistor ST1 in each of the string units SU0 to SU3 is connected to each of select gate lines SGD0 to SGD3. On the other hand, the gate of the select transistor ST2 in each of the string units SU0 to SU3 is commonly connected to, for example, select gate lines SGS. The gate of the select transistor ST2 in each of the string units SU0 to SU3 may be connected to the select gate lines SGS0 to SGS4 different for each string unit SU. The control gates of the memory cell transistors MT0 to MT63 in the same block BLK are commonly connected to word lines WL0 to WL63, respectively.

The drains of the select transistors ST1 of each NAND string 214 in the string unit SU are respectively connected to a different bit line BL (BL0 to BL(L−1), where L is a natural number of 2 or more). Further, the bit lines BL commonly connect one NAND string 214 in each string unit SU between the plurality of blocks BLK. Furthermore, the source of each select transistor ST2 is commonly connected to a source line SL.

That is, the string unit SU is a set of NAND strings 214 which are connected to different bit lines BL and connected to the same select gate line SGD. Further, the block BLK is a set of the plurality of string units SU sharing the word line WL. Then, the memory cell array 211 is a set of the plurality of blocks BLK sharing the bit line BL.

The program operation and the sense operation for one plane P by the processing circuit 210 are collectively performed for the memory cell transistor MT connected to one word line WL in one string unit SU. Hereinafter, the group of memory cell transistors MT that are collectively selected during the program operation and the sense operation for one plane P is referred to as a memory cell group WLSC. A storage area of a collection of data of one bit to be written to or read from one memory cell group WLSC is referred to as a “page”.

Hereinafter, the memory cell transistor MT will simply be referred to as a memory cell.

Each memory cell is capable of writing n (n≥1) bits of data. When n-bit data is written to each memory cell, the storage capacity per memory cell group WLSC is equal to the size of n pages. A mode in which n is 1 is referred to as a single level cell (SLC) mode. A mode in which n is 2 is referred to as a multi level cell (MLC) mode. A mode in which n is 3 is referred to as a triple level cell (TLC) mode. A mode in which n is 4 is referred to as a quad level cell (QLC) mode.

The threshold voltage of each memory cell is controlled within a certain range by the processing circuit 210. A controllable range of the threshold voltage is divided into 2ⁿ segments, and different values are respectively assigned to each segment.

Hereinafter, an example in which the memory cell is used in a TLC mode will be described. That is, each memory cell group WLSC is configured to have three pages. The embodiment is not limited to a system in which the memory cell is used in the TLC mode, and can be applied to a system in which the memory cell is used in any mode.

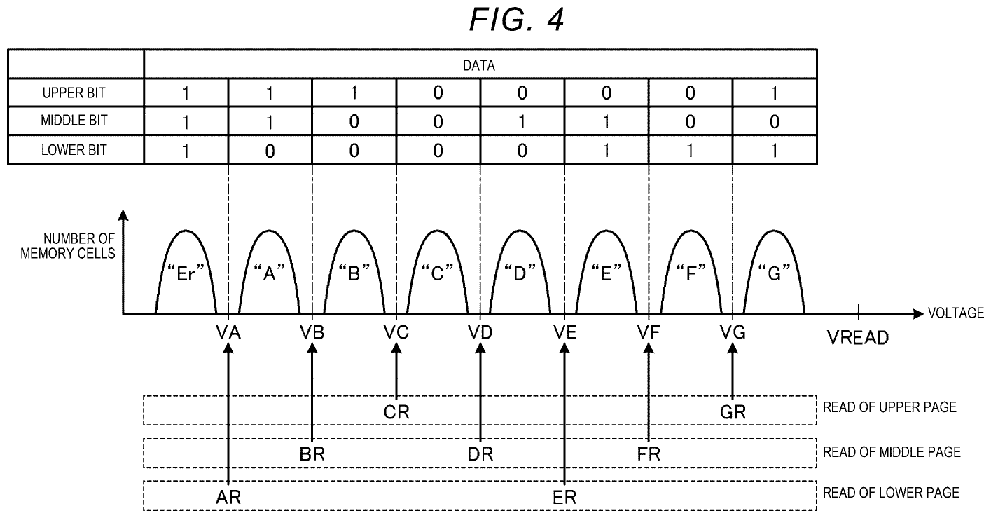

FIG. 4 is a diagram for illustrating an example of data coding according to the first embodiment.

As described above, in the TLC mode, 3-bit data is stored in each memory cell. Each bit constituting the 3-bit data stored in the memory cell is referred to as an upper bit, a middle bit, and a lower bit in order of arrangement. A page in which a group of upper bits among the three pages provided in a memory cell group MSG is stored is referred to as an upper page, a page in which a group of middle bits is stored is referred to as a middle page, and a page in which a group of lower bits is stored is referred to as a lower page.

According to the TLC mode, the range in which the threshold voltage can be taken is divided into eight ranges. The eight ranges are called an “Er” state, an “A” state, a “B” state, a “C” state, a “D” state, an “E” state, an “F” state, and a “G” state in ascending order of threshold voltage. The threshold voltage of each memory cell is controlled by the processing circuit 210 to belong to any of the “Er” state, the “A” state, the “B” state, the “C” state, the “D” state, the “E” state, the “F” state, and the “G” state. As a result, when the number of memory cells is plotted with respect to the threshold voltage, the memory cells form eight lobe-shaped distributions that do not overlap each other and respectively belong to different states, as illustrated in the middle of FIG. 4, ideally. Hereinafter, the distribution for each state may be simply referred to as a lobe.

The eight states correspond to 3-bit data. The upper table in FIG. 4 shows an example of a correspondence relationship between a state and 3-bit data, that is, data coding. According to this example, the “Er” state corresponds to “111”, the “A” state corresponds to “110”, the “B” state corresponds to “100”, the “C” state corresponds to “000”, the “D” state corresponds to “010”, the “E” state corresponds to “011”, the “F” state corresponds to “001”, and the “G” state corresponds to “101”. When the 3-bit data is described as “abc”, “a” is an upper bit, “b” is a middle bit, and “c” is a lower bit. As described above, each memory cell can store data corresponding to the state to which the threshold voltage thereof belongs. The correspondence relationship between the state and the data illustrated in FIG. 4 is an example of data coding. The data coding is not limited to the example in the drawing.

The threshold voltage is lowered to the “Er” state by the erase operation. Further, the threshold voltage is maintained at the “Er” state or rises until reaching any of the “A” state, the “B” state, the “C” state, the “D” state, the “E” state, the “F” state, and “G” state by the program operation.

Specifically, in the program operation, the processing circuit 210 selects the bit line BL corresponding to a column address. The processing circuit 210 sets the voltage of the selected bit line BL to zero. The processing circuit 210 selects the word line WL corresponding to a row address and applies a programming pulse to the selected word line WL. Then, electrons are injected into the charge storage layer of the memory cell positioned at the intersection of the selected bit line BL and the selected word line WL, and as a result, the threshold voltage of the memory cell rises. The processing circuit 210 reads data at a predetermined timing to check whether the threshold voltage of the memory cell reaches the target state corresponding to the write data (verify read). The processing circuit 210 continues applying a programming pulse until the threshold voltage of the memory cell reaches the target state.

Hereinafter, a memory cell of which the threshold voltage is set to a certain state by a program operation may be referred to as a memory cell belonging to the state.

A read level, which is a voltage for determining data, is set between two adjacent states. For example, as illustrated in FIG. 4, a read level VA is set between the “Er” state and the “A” state, a read level VB is set between the “A” state and the “B” state, a read level VC is set between the “B” state and the “C” state, a read level VC is set between the “C” state and the “D” state, a read level VE is set between the “D” state and the “E” state, a read level VF is set between the “E” state and the “F” state, and a read level VG is set between the “F” state and the “G” state.

In the sense operation, the processing circuit 210 sequentially applies a plurality of types of read levels to the selected word line WL and determines for each memory cell whether the memory cell is in a conductive state (in other words, an on state) or a non-conductive state (in other words, an off state) when each read level is applied. The processing circuit 210 determines data correlated with a state to which the memory cell belongs by performing a logical operation using the determination result obtained for each read level applied.

Hereinafter, the operation of applying a single type of read level VX (X is any of A to G) to the selected word line WL and determining for each memory cell whether the memory cell is in an on state or an off state will be referred to as X read, or in some drawings, further abbreviated to XR. The determination result by the X read is referred to as a determination result XR.

When the data coding illustrated in FIG. 4 is adopted, when a memory cell belongs to any of the “Er” state, the “E” state, the “F” state, and the “G” state, the lower bit of the data stored by that memory cell is “1”. When the memory cell belongs to any of the “A” state, the “B” state, the “C” state, and the “D” state, the lower bit of the data stored in the memory cell is “0”. Therefore, the processing circuit 210 determines the data of the upper page by using two types of read levels of VA and VE. Specifically, the processing circuit 210 performs the A-read and the E-read, and acquires the data of the lower page by a logical operation using the determination result AR obtained by the A-read and the determination result ER obtained by the E-read. That is, the lower page is a storage area from which data is read by using the read level VA and the read level VE.

When the memory cell belongs to any one of the “Er” state, the “A” state, the “D” state, and the “E” state, the middle bit of the data stored in the memory cell is “1”. When the memory cell belongs to any of the “B” state, the “C” state, the “F” state, and the “G” state, the middle bit of the data stored in the memory cell is “0”. Therefore, the processing circuit 210 determines the data of the middle page by using the three types of read levels of VB, VD, and VF. Specifically, the processing circuit 210 performs B-read, D-read, and F-read. The processing circuit 210 acquires the data of the middle page by performing a logical operation using the determination result BR obtained by B-read, the determination result DR obtained by D-read, and the determination result DF obtained by F-read. That is, the middle page is a storage area from which data is read by using the read level VB, the read level VD, and the read level VF.

When the memory cell belongs to any of the “Er” state, the “A” state, the “B” state, and the “G” state, the upper bit of the data stored in the memory cell is “1”. When the memory cell belongs to any of the “C” state, the “D” state, the “E” state, and the “F” state, the upper bit of the data stored in the memory cell is “0”. Therefore, the processing circuit 210 determines the data of the upper page by using two types of read levels of VC and VG. Specifically, the processing circuit 210 performs C-read and G-read, and acquires the data of the upper page by a logical operation using the determination result CR obtained by the C-read and the determination result GR obtained by the G-read. That is, the upper page is a storage area from which data is read by using the read level VC and the read level VG. As described above, the type of the read level used for determining the data is different depending on the type of the page which is the read target. The processing circuit 210 acquires data of the page, which is the read target, by combining determination results of whether the threshold voltage of the memory cell is higher or lower than the read level by using each of the plurality of types of read levels independently depending on the type of the page which is a target of the sense operation.

Hereinafter, the lower page, the middle page, and the upper page are referred to as page types.

FIG. 4 illustrates a case where the memory cells form eight lobes that do not overlap each other. Meanwhile, the threshold voltage of the memory cell may change due to various factors. For example, the threshold voltage of the memory cell tends to change according to time elapsed from the completion of the program operation. The speed of the change in the threshold voltage of the memory cell is fastest immediately after the program operation is completed, and slows down with the elapse of time. A memory cell in which the number of execution times of the erase operation and the program operation is larger is more likely to change in the threshold voltage. Also, the change in the threshold voltage of the memory cell may be affected by not only the time elapsed from the completion of the program operation, but also the sense operation on the memory cell, the sense operation on the adjacent memory cells, the temperature at the time of access, and the like. Since the threshold voltage of the memory cell may change, two adjacent lobes may actually overlap each other during the sense operation.

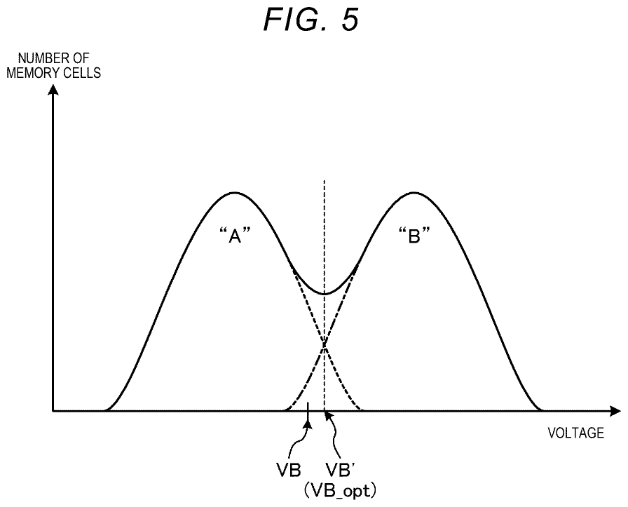

FIG. 5 is a diagram illustrating another example of the threshold voltages that may be taken by the memory cells according to the first embodiment. Here, the distribution of memory cells belonging to either the “A” state or the “B” state is illustrated in the drawing for ease of explanation. A solid line indicates the distribution of memory cells belonging to either the “A” state or the “B” state. A dashed line indicates the lobe in the “A” state and an alternate long and short dashed line indicates the lobe in the “B” state. In the example of the drawing, a part of the high voltage side of the lobe in the “A” state and a part of the low voltage side of the lobe in the “B” state overlap other. In other words, the maximum value of the threshold voltage of the memory cell belonging to the “A” state exceeds the read level VB, and the minimum value of the threshold voltage of the memory cell belonging to the “B” state is lower than the read level VB. When a memory cell belonging to the “A” state and having a threshold voltage higher than the read level VB is read, the memory cell is recognized as belonging to the “B” state. That is, data programmed as “110” is read as “100”. When a memory cell belonging to the “B” state and having a threshold voltage lower than the read level VB is read, the memory cell is recognized as belonging to the “A” state. That is, data programmed as “100” is read as “110”.

As described above, the data read by the sense operation may change from the value at the time of the program operation due to the change in the threshold voltage. The memory controller 10 corresponds to the change in the data and the threshold voltage by error correction or the like. Specifically, the memory controller 10 executes error correction on the read data by the ECC circuit 15. The memory controller 10 may include an error correction function that is stronger than the error correction function of the ECC circuit 15 when the error correction by the ECC circuit 15 fails. The case where the error correction fails means that data before change cannot be restored from data after change. Specifically, the case where the error correction fails means that an error bit in the read data cannot be corrected. A case where the error correction is successful means that all error bits in the read data are corrected.

The memory controller 10 has an upper limit on the error correction capability. The memory controller 10 is configured to perform a read operation by changing a read level value such that the errors of read data can be corrected by the error correction capability of the memory controller 10. The read operation performed by changing a read level value is referred to as a shift read.

The read level may be expressed in various amounts. In an example, a fixed value is set in advance for each type of read level (VA to VG), and the read level is represented by a shift amount (that is, a difference) from the fixed value. In addition, a fixed value is recorded in a predetermined position in the memory chip CP for each type of read level. In the shift read, the memory controller 10 instructs the memory chip CP on the shift amount from the fixed value for each type of read level.

The method of expressing the read level and the method of instructing the read level are not limited to the above. For example, the read level value is expressed by a net voltage value instead of a difference, and the read level may be instructed to the memory chip CP as the net voltage value.

In order to reduce the number of error bits generated during the read operation as much as possible, the memory controller 10 corrects the set value of the read level at a predetermined timing. The read level value that can minimize the number of error bits generated during the read operation is referred to as an optimal read level for convenience. For example, when the threshold voltage is distributed as illustrated in the graph of FIG. 5, a voltage value VB′ at which the distribution of the memory cells belonging to any one of the “A” state and the “B” state takes a local minimum is considered to be an optimal read level VB opt for to the read level VB.

The memory controller 10 corrects the set value of the read level by using a predetermined condition as a trigger, and accordingly, the number of error bits generated does not exceed an upper limit value determined by the error correction capability of the memory controller 10. Hereinafter, the operation of correcting the set value of the read level is simply referred to as a read level correction operation.

A sequential read method is one of the read methods for efficiently acquiring the data requested by the host 2 from the NAND memory 20.

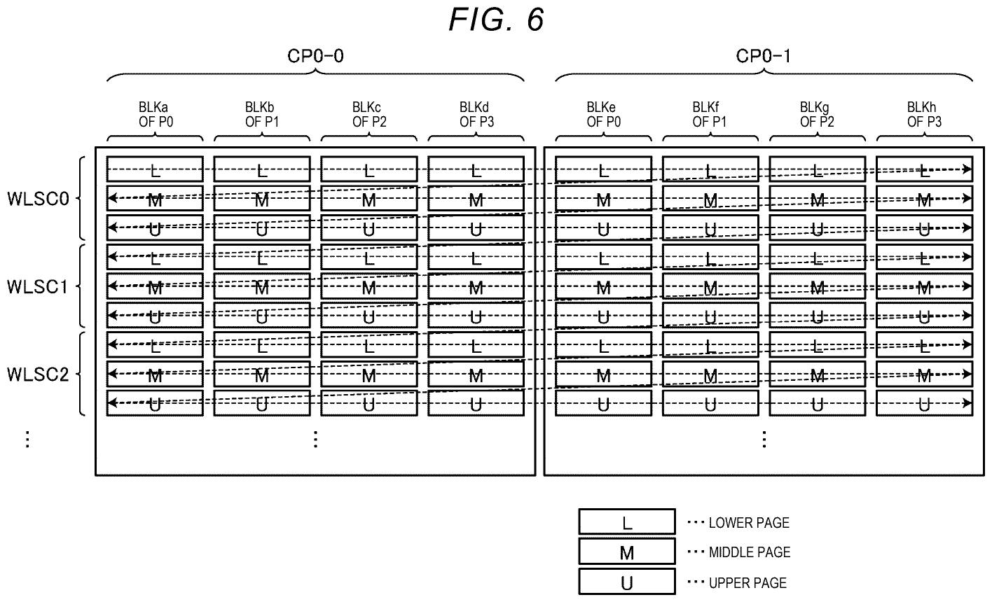

FIG. 6 is a diagram for illustrating an example of the sequential read method according to the first embodiment. In the example illustrated in the drawing, the memory chip CP is provided with four planes P (that is, the planes P0 to P3).

The memory controller 10 continuously executes the read operation on the memory chips CP0-0 and CP0-1 commonly connected to the channel CH0 in the order indicated by the dotted line in FIG. 6. The logical block is configured with the block BLKa of the plane P0, the block BLKb of the plane P1, the block BLKc of the plane P2, and the block BLKd of the plane P3, which are collected from the memory chip CP0-0, and the block BLKe of the plane P0, the block BLKf of the plane P1, the block BLKg of the plane P2, and the block BLKh of the plane P3, which are collected from the memory chip CP0-1. The memory controller 10 executes a read operation of the lower page of all the blocks BLK, a middle page read operation of all the blocks BLK, and a read operation of the upper page of all the blocks BLK, in this order, with respect to the logical block. The memory controller 10 executes, when the read operation of the lower page of all the blocks BLK, the middle page read operation of all the blocks BLK, and the read operation of the upper page of all the blocks BLK for one memory cell group WLSC end, a read operation of the lower page of all the blocks BLK, a middle page read operation of all the blocks BLK, and a read operation of the upper page of all the blocks BLK for another memory cell group WLSC.

All the planes P provided in CP0-0 and all the planes P provided in CP0-1 can operate independently of each other. However, CP0-0 and CP0-1 are commonly connected to the channel CH0. Therefore, during the execution of the data output operation for one plane P, the data output operation cannot be executed for the data acquired from the other pages or the command cannot be transferred via the channel CH0.

In the sequential read method, the memory controller 10 performs a sense operation for another plane P during a period in which the channel CH0 is occupied by the data output operation for a certain plane P. For example, the memory controller 10 causes the memory chip CP0-1 to execute a sense operation of acquiring data of the lower page of the memory cell group WLSC0 for the four planes P during a period in which a data output operation of outputting data of the lower page of the memory cell group WLSC0 for the four planes P to the memory chip CP0-0 is sequentially executed. Further, the memory controller 10 causes the memory chip CP0-0 to execute a sense operation of acquiring data of the middle page of the memory cell group WLSC0 for the four planes P during a period in which a data output operation of outputting data of the lower page of the memory cell group WLSC0 for the four planes P to the memory chip CP0-1 is sequentially executed.

As described above, according to the sequential read method, a period in which the channel CH is occupied by the data output operation is effectively used, and thus the total time required for reading the data from all the blocks BLK in the logical block is reduced. The memory controller 10 can efficiently read the data requested by the host 2 from the NAND memory 20 by such a method.

The read level correction operation requires a read operation (more precisely, a shift read) for the NAND memory 20. Therefore, when the sequential read method can be used in the read level correction operation, the efficiency of the read level correction operation is improved.

Two technologies will be described for comparison with the embodiment. The two technologies compared with the embodiments are referred to as a first comparative example and a second comparative example. According to the first comparative example and the second comparative example, a read level correction operation different from the read level correction operation of the embodiment is executed. The read level correction operation executed in the first comparative example and the second comparative example is referred to as a read level correction operation according to a comparative example.

According to the read level correction operation according to the comparative example, the memory controller reads data from pages of all page types (for example, the lower page, the middle page, and the upper page) of one memory cell group WLSC. Then, the memory controller compares the data before error correction with the data after error correction for the data read from the page of each page type, and acquires the number of bits in which data corresponding to the “Si” state was erroneously read as data corresponding to the “Si+1” state adjacent to the “Si” state, and the number of bits in which data corresponding to the “Si+1” state was erroneously read as data corresponding to the “Si” state. The “Si” state is the “Er” state, the “A” state, the “B” state, the “C” state, the “D” state, the “E” state, or the “F” state. The “Si+1” state is a state adjacent to the “Si” state on a high voltage side among the “A” state, the “B” state, the “C” state, the “D” state, the “E” state, the “F” state, and the “G” state. The memory controller estimates an optimal read level corresponding to the boundary between the “Si” state and the “Si+1” state based on the ratio between the number of bits in which data corresponding to the “Si” state is erroneously read as data corresponding to the “Si+1” state adjacent to the “Si” state and the number of bits in which data corresponding to the “Si+1” state is erroneously read as data corresponding to the “Si” state. The memory controller acquires the number of bits in which data corresponding to the “Si” state is erroneously read as data corresponding to the “Si+1” state adjacent to the “Si” state, and the number of bits in which data corresponding to the “Si+1” state is erroneously read as data corresponding to the “Si” state, and estimates an optimal read level based on a ratio of the acquired numbers of bits, for each read level.

In the first comparative example, the memory controller uses a sequential read method in the read level correction operation according to the comparative example. According to the example of the sequential read method illustrated in FIG. 6, until the read of pages of all page types of one memory cell group WLSC is completed, the data before error correction and the data after error correction, which are read from the pages of the two page types (that is, the lower page and the middle page) for each of the other seven memory cell groups WLSC having the plane P or the memory chip CP different from the plane P or the memory chip CP of the one memory cell group WLSC, need to be stored in the buffer (for example, RAM). Therefore, in the first comparative example, a large-capacity buffer is required, which is disadvantageous in terms of cost.

In the second comparative example, the memory controller executes a read operation in a dedicated method different from the sequential read method. The memory controller sequentially and continuously executes reading for the same memory cell group WLSC in order to acquire data from pages of all page types of one memory cell group WLSC. For example, the memory controller reads pages of all the page types for the memory cell group WLSC0 of the block BLKa belonging to the plane P0 of the memory chip CP0-0. After that, the memory controller reads pages of all the page types for the memory cell group WLSC0 of the block BLK belonging to the plane P1 of the memory chip CP0-0. In this manner, the memory controller sequentially switches the read unit targeted for the read level correction operation, treating the read of pages of all page types for one memory cell group WLSC of one block BLK belonging to one plane P of one memory chip CP as one read unit.

However, in the second comparative example, the efficiency of acquiring data from the NAND memory is lower than when the read operation is executed in the sequential read method. Furthermore, it becomes necessary to switch the read method between the reading of data requested by the host and the read level correction operation according to the comparative example, which complicates the control in the memory controller.

In contrast, in the embodiment, the memory controller 10 can execute the read level correction operation that can be executed by using the sequential read method without requiring a large-capacity buffer. Next, the read level correction operation according to the embodiment will be described.

In the embodiment, the memory controller 10 executes the read level correction operation using the technologies of D-optimal design and response surface methodology from the experimental design method. According to the present technology, a model matrix corresponding to a model formula and a design matrix are prepared in advance. The design matrix is a matrix obtained by arranging a plurality of vectors in a vertical direction, each of the vectors being configured with arranging specific values of the linear terms of the explanatory variables in the model formula in a horizontal direction. The model matrix is a matrix obtained by arranging a plurality of vectors in a vertical direction, each of the vectors being configured with arranging specific values of all explanatory variables in the model formula in a horizontal direction. Therefore, the design matrix is also a submatrix of the model matrix. A vector of specific values of the objective variable can be represented by a product of a model matrix and a coefficient vector collecting coefficients of a model formula. In the embodiment, a design matrix in which specific values of a read level value (or a change amount of the read level value) are arranged is set in advance based on a model formula with at least a read level value (or a change amount of the read level value) as an explanatory variable.

Specifically, in the read level correction operation, the memory controller 10 changes the read level value according to a design matrix set in advance (a matrix D to be described later) and executes the shift read for the pages of the same page type of the plurality of different memory cell groups WLSC. The memory controller 10 acquires the FBC for each of the plurality of data read from the pages of the same page type of the plurality of different memory cell groups WLSC. The memory controller 10 calculates a correction amount for bringing the read level closer to the optimal read level, in other words, a correction amount of the read level for reducing the number of error bits generated at the time of reading, based on the acquired group of FBCs and the pseudo-inverse matrix of the model matrix.

The memory controller 10 executes the read level correction operation for each page type. That is, the read level correction operation includes an operation of correcting a read level (that is, read levels VA and VE) required for a read operation of a lower page, an operation of correcting a read level (that is, read levels VB, VD, and VF) required for a read operation of a middle page, and an operation of correcting a read level (that is, read levels VC and VG) required for a read operation of an upper page. An operation of correcting a read level required for a read operation of a lower page is referred to as a read level correction operation for a lower page. An operation of correcting a read level required for a read operation of a middle page is referred to as a read level correction operation for a middle page. An operation of correcting a read level required for a read operation of an upper page is referred to as a read level correction operation for an upper page.

First, a read level correction operation for a lower page will be described.

The model matrix is generated based on a model formula in which the FBC is an objective variable and the read level is an explanatory variable.

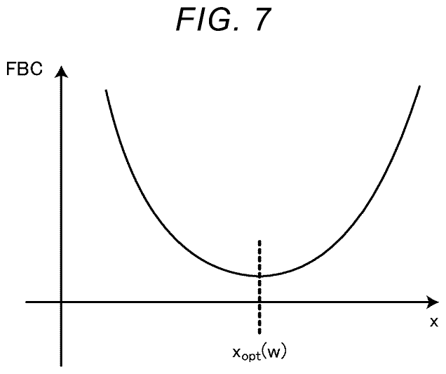

For example, as illustrated in FIG. 7, it is considered that the FBC caused by one read level in the periphery of the optimal read level for one read level can be approximated by a polynomial of two or more orders of the one read level value. In FIG. 7, x indicates a read level value, and the vertical axis indicates an FBC. xₒₚₜ indicates an optimal read level. It is considered that the optimal read level depends on an offset from the head of a word line group within a certain range in one block BLK. Therefore, the FBC caused by one read level can be represented by the following Formula (1) in an example.

$$FBC = {a ( x - {x}_{opt} ( w ) )}^{2} + b \qquad ( 1 )$$

In Formula (1), w is an offset from a head of a word line group within a certain range. Hereinafter, w is referred to as a word line offset. A more specific description of the word line offset will be described below. a and b are constants.

The FBC of the data obtained by the read operation for one page is considered to be equal to a value obtained by adding the FBCs of the determination results obtained by the read using one read level for a plurality of types of read levels required for the read operation for that page. In addition, it is considered that the FBC generated by the read operation also depends on the word line offset.

Therefore, the FBC generated by the read operation for the lower page can be assumed to be represented by the model formula to be described below.

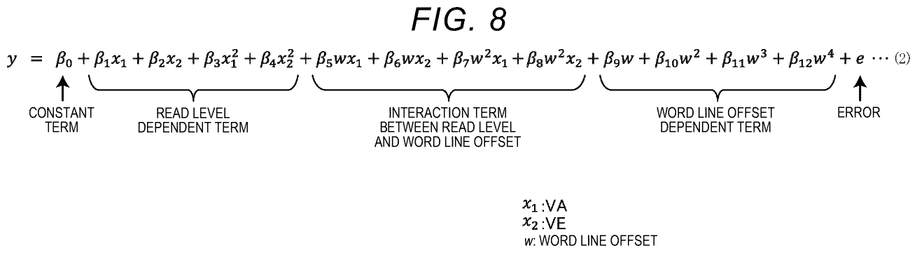

FIG. 8 is a diagram illustrating a model formula of the first embodiment representing the FBC generated by the read operation for the lower page. In Formula (2) illustrated in the drawing, x₁ represents a read level value VA, and x₂ represents a read level value VE. w is a word line offset. β₀ to β₁₂ are coefficients. y is FBC. e is an error.

According to the model formula illustrated in Formula (2), y, which is the FBC, is represented as a sum of a constant term, a read level dependent term, an interaction term between the read level and the word line offset, a word line offset dependent term, and an error. The read level dependent term includes a first order term in x₁, a first order term in x₂, a second order term in x₁, and a second order term in x₂. The word line offset dependent term includes a first order term, a second order term, a third order term, and a fourth order term of the word line offset. The interaction term includes a term obtained by multiplying w by x₁, a term obtained by multiplying w by x₂, a term obtained by multiplying w squared by x₁, and a term obtained by multiplying w squared by x₂.

The word line offset dependent term is a fourth order polynomial, but the order of the word line offset dependent term is not limited to 4. Further, the order of w in the interaction term is set to 2, but the order of w in the interaction term is not limited to 2. The designer can observe the actual phenomenon and create a model formula of a polynomial including at least the read level and the word line offset.

The memory controller 10 changes one or both of the read level VA and the read level VE to perform a read operation for the lower pages of each different memory cell group WLSC. The memory controller 10 performs regression analysis with Formula (2) as a model formula based on the results (FBC) of the read operation for the lower pages of each different memory cell group WLSC, and thereby estimates the coefficients β₀ to β₁₂.

The set of storage areas (here, lower pages) that are acquisition targets of the FBC are selected from each different memory cell group WLSC. A set of storage areas that are acquisition targets of the FBC is referred to as a correction unit in the present specification.

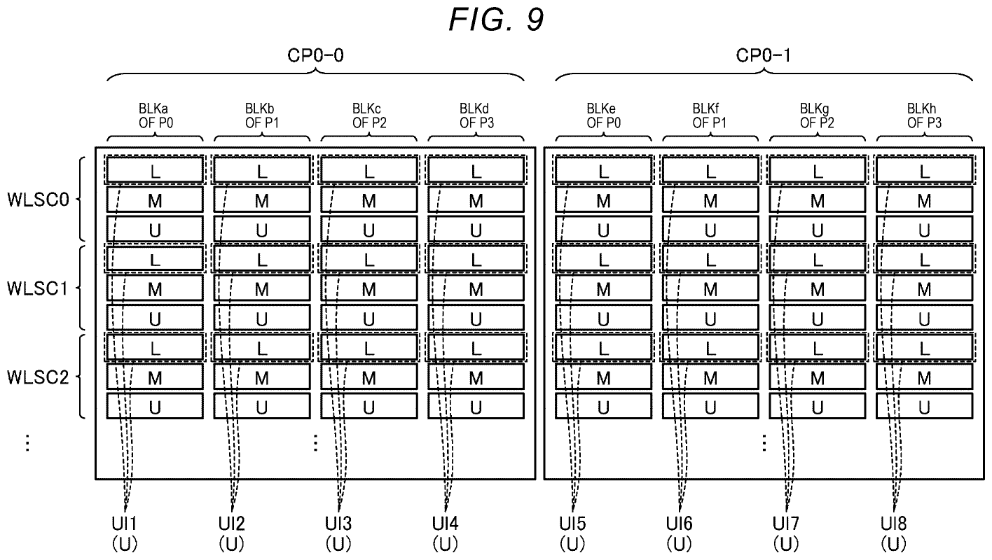

FIG. 9 is a diagram illustrating an example of a configuration of the correction unit for the read level correction operation for the lower page of the first embodiment.

For example, one correction unit U11 is configured with the lower page of the memory cell group WLSC0, the lower page of the memory cell group WLSC1, and the lower page of the memory cell group WLSC2 among the block BLKa provided in the page P0 of the memory chip CP0-0.

In addition, another correction unit U12 is configured with the lower page of the memory cell group WLSC0, the lower page of the memory cell group WLSC1, and the lower page of the memory cell group WLSC2 among the block BLKb provided in the page P1 of the memory chip CP0-0.

In addition, another correction unit U13 is configured with the lower page of the memory cell group WLSC0, the lower page of the memory cell group WLSC1, and the lower page of the memory cell group WLSC2 among the block BLKc provided in the page P2 of the memory chip CP0-0.

In the same manner, the correction units U14 to C18 are configured.

In this manner, the correction unit U is configured with the lower page of each of the predetermined numbers (referred to as N) of memory cell groups WLSC. N is an integer of 2 or more. However, N may be set to be a number larger than the number of coefficients β such that the coefficients β₀ to β₁₂ can be accurately estimated. In FIG. 9, the number of storage areas constituting each correction unit U is set to three in order to prevent the drawing from becoming complicated.

A pattern of changing the read level (that is, one or both of the read level VA and the read level VE) used in the read operation of the lower page is determined based on an experimental design method. A design matrix indicating a change pattern of a read level and a model matrix including a part of the design matrix are set in advance based on an experimental design method. The memory controller 10 changes the read level for each storage area in one correction unit U according to the design matrix, and performs the shift read for each storage area. The memory controller 10 calculates the coefficients β₀ to β₁₂ by using a group of FBCs obtained by performing the shift read for each storage area and a pseudo-inverse matrix of the model matrix.

Hereinafter, the design matrix is referred to as a design matrix D. The model matrix is referred to as a model matrix X. The design matrix D and the model matrix X (and a pseudo-inverse matrix A to be described later) are defined for each type of page. Each matrix for the lower page is given a subscript l. Each matrix for the middle page is given a subscript m. Each matrix for the upper page is given a subscript u.

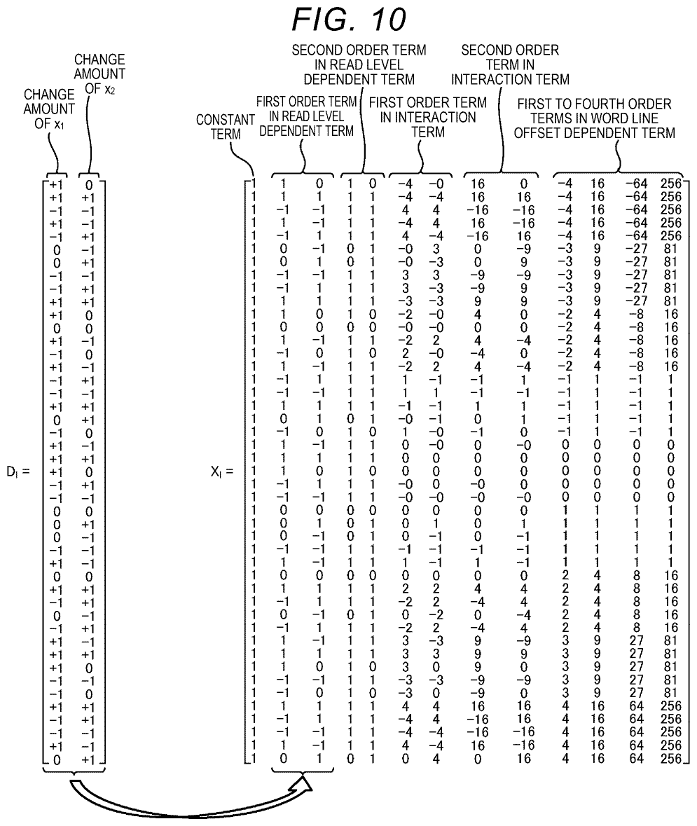

FIG. 10 is a diagram illustrating an example of a design matrix D₁ and a model matrix X₁ related to the read level correction operation for the lower page of the first embodiment.

The design matrix D₁ and the model matrix X₁ have N rows, which are the same as the number of storage areas configuring one correction unit U. An arrangement of N rows of the design matrix D₁ and the model matrix X₁ corresponds to an arrangement of N storage areas constituting the correction unit U.

In the example illustrated in FIG. 10, one block BLK has five string units SU. The memory cell group WLSC is selected for each string unit SU from the nine word lines of which word line numbers are continuous, and one correction unit U is configured with the lower pages of the selected 45 memory cell groups WLSC(=9 word lines x 5 string units). Therefore, the design matrix D₁ and the model matrix X₁ have 45 rows, which are the same as the number of storage areas constituting one correction unit U.

An arrangement of storage areas configuring the correction unit U is equal to an execution order of a read operation by a sequential read method for the 45 storage areas configuring the correction unit U, as an example. Here, the lower pages of five memory cell groups WLSC in the same word line and each belonging to different string units SU are treated as one set, and a read operation is executed in the order of the word line numbers. Therefore, the arrangement of the design matrix D₁ and the model matrix X₁ corresponds to the arrangement of storage areas arranged in the order of word line numbers in units of lower pages for five memory cell groups WLSC in the same word line and each belonging to different string units SU.

A word line offset of each word line in a range of nine word lines having consecutive word line numbers is set as a relative value with a median value of word line numbers of the nine word lines as a reference (that is, 0). For example, the word line offset (that is, the value of w) of the nine word lines having the word line numbers in the range of i to i+8 is set as follows. That is, the word line offset of the word line having the word line number i is set to “−4”, the word line offset of the word line having the word line number i+1 is set to “−3”, the word line offset of the word line having the word line number i+2 is set to “−2”, the word line offset of the word line having the word line number i+3 is set to “−1”, the word line offset of the word line having the word line number i+4 is set to “0”, the word line offset of the word line having the word line number i+5 is set to “1”, the word line offset of the word line having the word line number i+6 is set to “2”, the word line offset of the word line having the word line number i+7 is set to “3”, and the word line offset of the word line having the word line number i+8 is set to “4”.

It is considered that the word line offset set in this manner indicates the word line position in the memory cell group WLSC. The setting method of the word line offset is not limited to the above-described example as long as the word line unit position in the memory cell group WLSC is indicated.

Each row of the design matrix D₁ is a vector having the change amount of x₁ (that is, the read level VA) and the change amount of x₂ (that is, the read level VE) as elements. That is, each row of the design matrix D₁ defines a change pattern of the read level. The unit of each change amount is a minimum change amount in a read level generated by a digital-to-analog converter provided in the processing circuit 210. This minimum change amount may be referred to as a DAC.

Each row of the model matrix X is a vector that arranges the values multiplied by each of the coefficients β₀ to β₁₂ when the change amount of x₁ and the change amount of x₂ defined by the design matrix D₁ are substituted into x₁ and x₂ in Formula (2).

For example, according to the first row of the design matrix D₁, a change pattern is defined in which x₁ is changed to “+1” DAC and x₂ is not changed. In the first row of the model matrix X₁ corresponding to this, “1” is set in a position corresponding to a constant term, “1” identical to the change amount of x₁ and “0” identical to the change amount of x₂ are set in positions corresponding to the first order term of the read level dependent term, and “1” obtained by squaring 1 and “0” obtained by squaring 0 are set in positions corresponding to the second order term of the read level dependent term. For the word line offset dependent term, −4 is set as w, and “−4”, “16” obtained by squaring −4, “−64” obtained by cubing −4, and “256” obtained by raising −4 to the fourth power are set at positions corresponding to the word line offset dependent term. At a position corresponding to the first order term of the interaction term, “−4” obtained by multiplying w (that is, −4) by a change amount (that is, 1) of x₁, and “−0” obtained by multiplying w (that is, −4) by a change amount (that is, 0) of X₂ are set. At a position corresponding to the second order term of the interaction term, “16” obtained by multiplying the square of w (that is, −4) by a change amount (that is, 1) of x₁, and “0” obtained by multiplying the square of w (that is, −4) by a change amount (that is, 0) of x₂ are set.

As described above, the model matrix X₁ corresponds to the design matrix D₁ and the model formula, which is Formula (2).

The two columns corresponding to the first order term of the read level dependent term in the model matrix X₁ coincide with the design matrix D₁. That is, the design matrix D₁ is also a part of the model matrix X₁.

The design matrix D₁ and the model matrix X₁ are determined by a designer. When the design matrix D₁ is determined, the model matrix X₁ is determined based on the design matrix D₁ and the model formula (that is, Formula (2)). The designer can determine the design matrix D₁ based on the D-optimality criterion such that the coefficients β₀ to β₁₂ can be estimated with high accuracy by a small number of read operations. The determination method of the design matrix D₁ is not limited to the method based on the D-optimality criterion.

A vector having coefficients β₀ to β₁₂ as elements is referred to as a coefficient vector β. A vector having the FBC obtained by the read operation for each storage area constituting one correction unit as an element is referred to as an FBC vector Y. The coefficient vector β and the FBC vector Y are also provided with a subscript 1, a subscript m, or a subscript u depending on the page type of the page which is the read target.

A relationship of the following Formula (3) is present between the coefficient vector β₁, the FBC vector Y₁, and the model matrix X₁.

$${{Y}_{1}}^{t} {}_{}^{\cdot } {=}_{\cdot }^{} {X}_{1} {{β}_{1}}^{t} \qquad ( 3 )$$

Therefore, the coefficient vector β₁ may be estimated by the following Formula (4).

$${{β}_{1}}^{t} = {( {{X}_{1}}^{t} {X}_{1} )}^{- 1} {{X}_{1}}^{t} {{Y}_{1}}^{t} \qquad ( 4 )$$

To enable the memory controller 10 to acquire the coefficient vector β₁ by estimation, the pseudo-inverse matrix A₁ of the model matrix X₁ represented by the following Formula (5) is given to the memory controller 10 in advance by the designer.

$${A}_{1} = {( {{X}_{1}}^{t} {X}_{1} )}^{- 1} {{X}_{1}}^{t} \qquad ( 5 )$$

When the FBC vector Y₁ is acquired, the memory controller 10 acquires the coefficient vector β₁ by performing a calculation of the following Formula (6) using the FBC vector Y₁ and the pseudo-inverse matrix A₁.

$${{β}_{1}}^{t} = {A}_{1} {{Y}_{1}}^{t} \qquad ( 6 )$$

When the coefficient vector β₁ is acquired, the memory controller 10 acquires a correction amount for bringing the read level value closer to an optimal value by using the coefficients β₁ to β₄ which are the coefficients in the read level dependent term among the coefficients β₀ to β₁₂ in the coefficient vector β₁. Hereinafter, the correction amount for bringing the read level value closer to the optimal value is simply referred to as a correction amount.

For example, y_{VA} which is the FBC with respect to the read level VA is represented as in the following Formula (7) by using the coefficients β₁ and β₃ in the read level dependent term. The C_{VA} is a constant.

$${y}_{VA} = {β}_{1} {x}_{1} + {β}_{3} {x}_{1}^{2} + {c}_{VA} \qquad ( 7 )$$

As described with reference to FIGS. 7 and 8, it is expected that Formula (7) becomes a quadratic function that is convex downward. That is, the sign of the coefficient β₃ should be positive. Therefore, a value of x₁ at which y_{VA} of Formula (7) takes a local minimum (or a minimum value) is set as a correction amount ΔVA of the read level VA.

The FBC related to the read level VE is also represented as y_{VE} in the same manner as in the following Formula (8) by using the coefficients β₂ and β₄ in the read level dependent term. The CVE is a constant.

$${y}_{VE} = {β}_{2} {x}_{2} + {β}_{4} {x}_{2}^{2} + {c}_{VE} \qquad ( 8 )$$

It is also expected that Formula (8) becomes a quadratic function convex downward as in Formula (7). That is, the sign of the coefficient β₄ should be positive. Therefore, a value of x₂ at which y_{VE} of Formula (8) takes a local minimum (or a minimum value) is set as a correction amount ΔVE of the read level VE.

As described above, the read level is changed in units of DAC. Therefore, the correction amounts ΔVA and ΔVE are integer values. That is, the memory controller 10 acquires an integer value closest to a value of x₁ at which y_{VA} of Formula (7) takes a local minimum (or a minimum value) as a correction amount ΔVA. The memory controller 10 acquires an integer value closest to a value of x₂ at which y_{VE} of Formula (8) takes a local minimum as a correction amount ΔVE.

The memory controller 10 acquires the correction amounts ΔVA and ΔVE based on Formula (7) and Formula (8), and corrects the read levels VA and VE by using the acquired correction amounts ΔVA and ΔVE. As a result, each of the read levels VA and VE can be brought closer to the optimal read level.

The read level correction operation for the middle page is also executed in the same manner as the read level correction operation for the lower page.

In the read level correction operation for the middle page, the correction unit U is also configured.

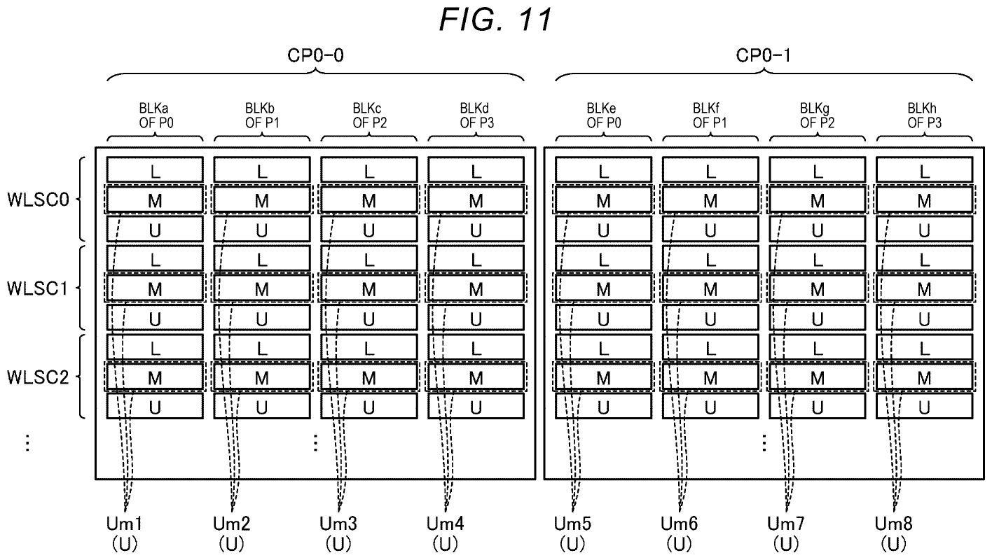

FIG. 11 is a diagram illustrating an example of a configuration of the correction unit for the read level correction operation for the middle page of the first embodiment. The plurality of correction units U are set as the correction units Um1 to Cm8 illustrated in this drawing.

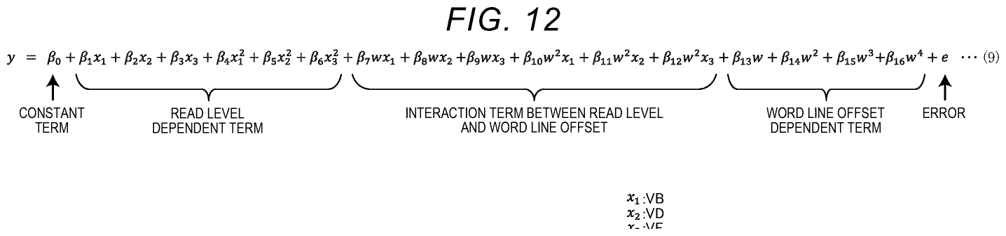

FIG. 12 is a diagram illustrating a model formula of the first embodiment representing the FBC generated by the read operation for the middle page. In Formula (9), which is a model formula representing the FBC generated by the read operation for the middle page, x₁ represents the value of the read level VB, X₂ represents the value of the read level VD, and x₃ represents the value of the read level VF. w is a word line offset. β₀ to β₁₆ are coefficients. y is FBC. e is an error.

The number of read levels required for the read operation for the lower page is one more than the number of read levels required for the read operation for the lower page. Therefore, according to Formula (9), the number of terms in the read level dependent term and the number of terms in the interaction term are each two more than those in Formula (2). Therefore, the number of coefficients β in Formula (9) is four more than the number of coefficients β in Formula (2).

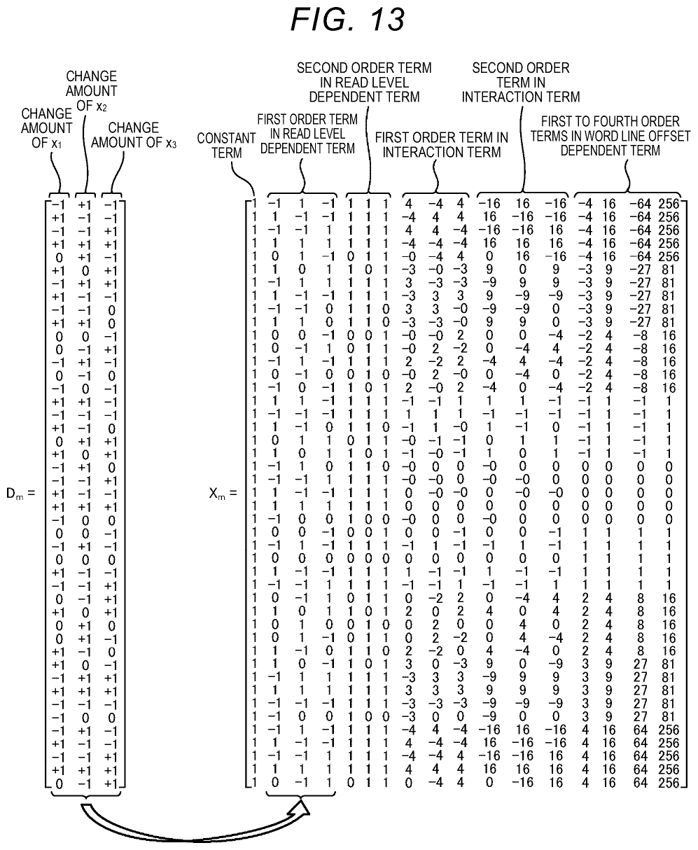

FIG. 13 is a diagram illustrating an example of the design matrix Dₘ and the model matrix Xₘ related to the read level correction operation for the middle page of a second embodiment.

As with the design matrix D₁ and the model matrix X₁, the arrangement of the rows of the design matrix Dₘ and the model matrix Xₘ corresponds to the arrangement of the 45 storage areas constituting one correction unit U.

Each row of the design matrix Dₘ is a vector having the change amount of x₁ (that is, the read level VB), the change amount of x₂ (that is, the read level VD), and the change amount of x₃ (that is, the read level VF) as elements.

Each row of the model matrix Xₘ is a vector in which values applied to each of the coefficients β₀ to β₁₆ are arranged when the change amount of x₁, the change amount of x₂, and the change amount of x₃ defined by the design matrix Dₘ are substituted for x₁, x₂, and x₃ in Formula (9).

Regarding the read level correction operation for the middle page, the model matrix Xₘ is also generated to correspond to the design matrix Dₘ and Formula (9) which is the model formula. In addition, the three columns corresponding to the first order term of the read level dependent term of the model matrix Xₘ coincide with the design matrix Dₘ.

The design matrix Dₘ and the model matrix Xₘ are determined by a designer. When the design matrix Dₘ is determined, the model matrix Xₘ is determined based on the design matrix Dₘ and the model formula (that is, Formula (9)). The designer can determine the design matrix Dₘ based on the D-optimality criterion. The determination method of the design matrix Dₘ is not limited to the method based on the D-optimality criterion.

Regarding the read level correction operation for the middle page, the pseudo-inverse matrix Aₘ of the model matrix Xₘ is given to the memory controller 10 in advance by the designer. Similar to the read level correction operation for the upper page, the memory controller 10 acquires the coefficient vector βₘ by calculation using the FBC vector Yₘ and the pseudo-inverse matrix Aₘ, and acquires the correction amount for each of the read levels VB, VD, and VF by using the coefficients β₁ to β₆ which are the coefficients in the read level dependent term of the acquired coefficient vector βₘ.

Even in the read level correction operation for the upper page, the correction unit U is configured.

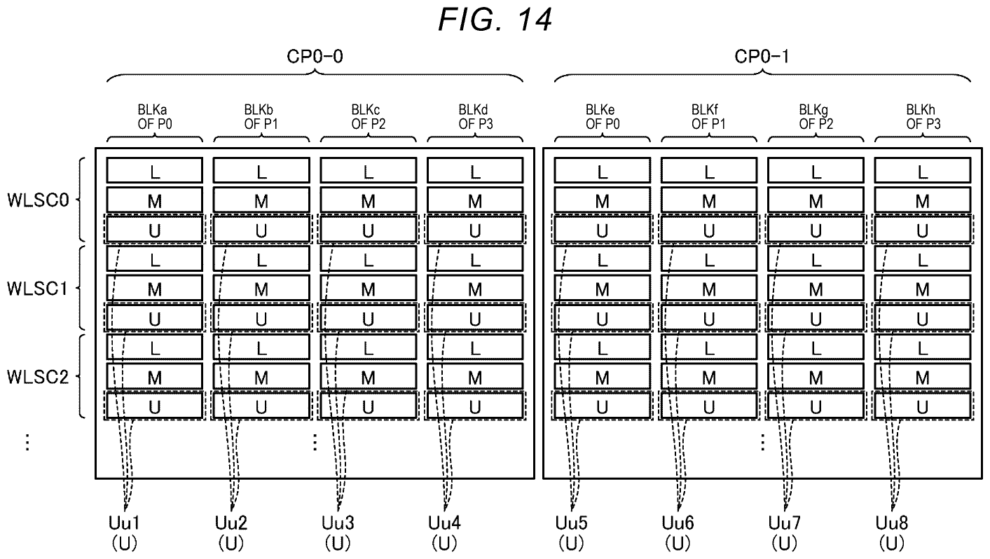

FIG. 14 is a diagram illustrating an example of a configuration of the correction unit for the read level correction operation for the upper page of the first embodiment. As illustrated in this drawing the correction units Uu1 to Uu8 illustrated in this drawing, the plurality of correction units U are set such that the upper pages of each memory cell group WLSC are in one of the correction units.

In the read operation for the upper page, two read levels (that is, the read levels VC and VG) are used, which are the same as the number of read levels required for the read operation for the lower page. Therefore, a design matrix Dᵤ having the same configuration as the design matrix D₁ and a pseudo-inverse matrix Aᵤ of the model matrix Xᵤ having the same configuration as the model matrix X₁ are used. The values of each element of the design matrix Dᵤ may be the same as or may be different from the design matrix D₁. The values of each element of the pseudo-inverse matrix Aᵤ may be the same as or may be different from the pseudo-inverse matrix A₁. Since the read level correction operation for the upper page is executed in the same manner as the read level correction operation for the lower further detailed page, description will be omitted.

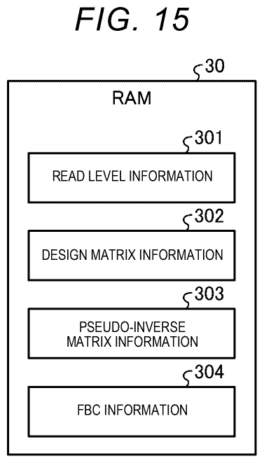

FIG. 15 is a diagram illustrating an example of data stored in a RAM 30 provided in the memory system 1 according to the first embodiment.

The RAM 30 stores read level information 301, design matrix information 302, pseudo matrix information 303, and FBC information 304.

The design matrix information 302 is information in which the design matrix D₁, the design matrix Dₘ, and the design matrix Dᵤ are recorded.

The pseudo matrix information 303 is information in which the pseudo-inverse matrix A₁, a pseudo-inverse matrix Aₘ, and a pseudo-inverse matrix Aᵤ are recorded.

The design matrix information 302 and the pseudo matrix information 303 are given as setting information. For example, the designer generates the design matrix information 302 and the pseudo matrix information 303 by calculation. The generated design matrix information 302 and the pseudo matrix information 303 are stored in the non-volatile memory in the memory system 1 (for example, the NAND memory 20) at the time of manufacturing the memory system 1 or the like. During the operation of the memory system 1, the design matrix information 302 and the pseudo matrix information 303 are loaded from the non-volatile memory to the RAM 30, and the memory controller 10 executes the read level correction operation by using the design matrix information 302 and the pseudo matrix information 303 loaded in the RAM 30.

The read level information 301 is information in which the current set values of the read levels VA to VG of each memory cell group WLSC are recorded. In a read operation of reading data requested by the host 2, the memory controller 10 performs a shift read using the set value recorded in the read level information 301.

In the first embodiment, the set value of the read level is corrected for each correction unit U. Therefore, the set value of the read level for each correction unit U is recorded in the read level information 301.

The FBC information 304 is information in which a group of FBCs acquired in the read level correction operation is recorded. The memory controller 10 records the FBC obtained by the shift read for each storage area in the FBC information 304 in the read level correction operation.

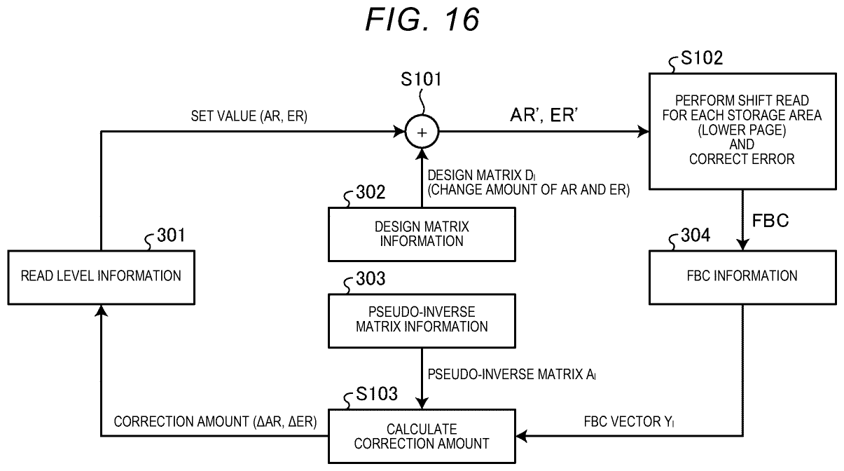

FIG. 16 is a schematic diagram for illustrating a data flow in the read level correction operation according to the first embodiment. Here, in order to facilitate understanding, a read level correction operation for a lower page with respect to a certain correction unit U (referred to as a target correction unit U in the description of FIG. 16) will be described.

The CPU 11 acquires set values of the read levels AR and ER used in the read operation for the storage area constituting the target correction unit U from the read level information 301. The CPU 11 acquires the design matrix D₁ from the design matrix information 302. The CPU 11 generates values of the read levels AR and ER used for the shift read by adding the change amount in the read levels AR and ER defined by the design matrix D₁ to the set values of the read levels AR and ER (S101). A value of the read level AR used for the shift read is referred to as a read level AR′, and a value of the read level ER used for the shift read is referred to as a read level ER′.

In the design matrix D₁, the change amount of the read levels AR and ER is defined for each storage area configuring one correction unit U. In S101, the CPU 11 generates the read levels AR′ and ER′ for each storage area. That is, the values of the read levels AR and ER are changed for each storage area in a change pattern defined by each different row of the design matrix D₁.

The CPU 11 controls the memory controller 10 to execute the shift read using the read levels AR′ and ER′ and the error correction for the data obtained by the shift read, for each storage area configuring the target correction unit U (here, the lower page of each memory cell group WLSC) (S102).

The CPU 11 acquires the FBC for each storage area configuring the target correction unit U by the S102, and records the acquired FBC in the FBC information 304.

After the FBC is acquired for all the storage areas configuring the target correction unit U, the CPU 11 calculates the correction amounts ΔAR and ΔER (S103). The CPU 11 corrects the set values of the read levels AR and ER by adding the correction amounts ΔAR and ΔER to the set values of the read levels AR and ER. The CPU 11 updates the set values of the read levels AR and ER recorded in the read level information 301 with the corrected set values.

As is clear: from the description of FIG. 16, according to the first embodiment, information indicating the FBC is temporarily stored in the buffer (here, the RAM 30) for all the storage areas configuring each correction unit U. Therefore, the capacity required for the buffer can be significantly reduced compared to Comparative Example 1 and Comparative Example 2, in which the read level correction operation according to the comparative example, which requires a pair of data before error correction and data after error correction, is executed. That is, according to the first embodiment, it is possible to appropriately correct the read level value.

In addition, since the capacity of the buffer required per one correction unit U is significantly smaller than that in the read level correction operation according to the comparative example, the shift read in the read level correction operation can be executed in the order of the sequential read method while the capacity of the buffer required is reduced as compared with that in Comparative Example 1. The read level value can be appropriately corrected in terms of being able to execute the read level correction operation in a short time.

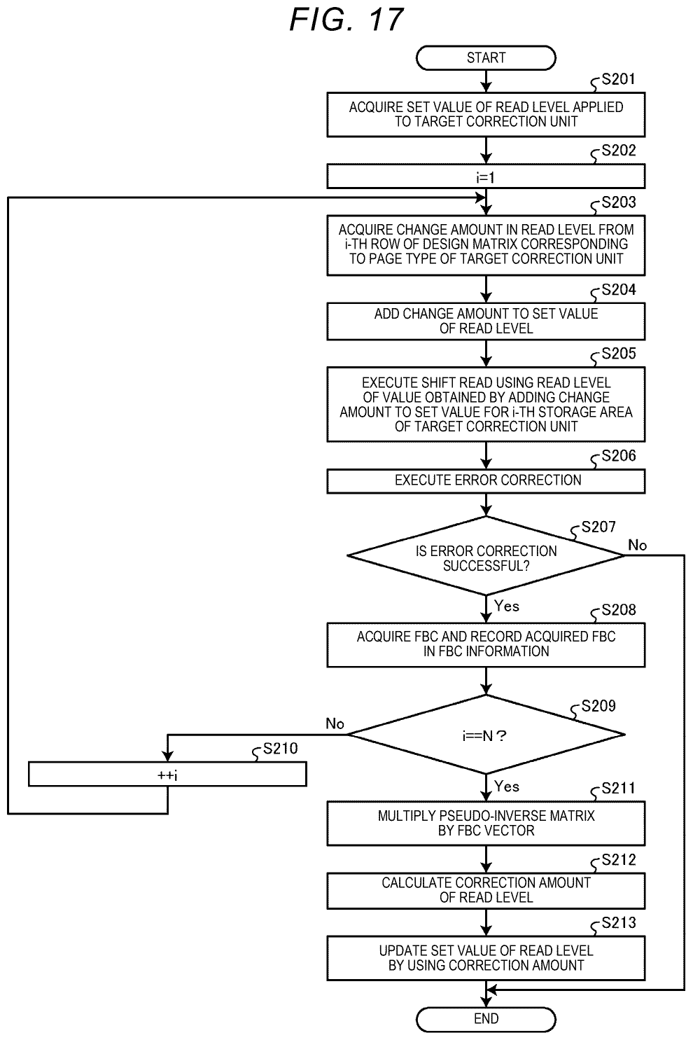

FIG. 17 is a flowchart illustrating an example of an operation of the memory system 1 according to the first embodiment. Here, a read level correction operation targeting one correction unit U (referred to as a target correction unit U in the illustration of FIG. 17) will be described.

First, the CPU 11 acquires a set value of the read level for the target correction unit U from the read level information 301 (S201).

Subsequently, the CPU 11 initializes an index i for loop processing in S203 to S210 to 1 (S202). The loop processing of S203 to S210 is executed for each storage area in the target correction unit U. That is, when the number of storage areas in the target correction unit U is N, the loop processing in S203 to S210 is executed N times.

The CPU 11 acquires the change amount in the read level from the i-th row of the design matrix D corresponding to the page type of the target correction unit (S203). The CPU 11 adds the change amount to the set value of the read level (S204).

The CPU 11 controls the memory controller 10 to execute shift read using a read level of a value obtained by adding a change amount to a set value for an i-th storage area of the target correction unit U (S205).

The ECC circuit 15 executes error correction on data read from the i-th storage area of the correction unit U by the shift read in S205 (S206).

When the error correction fails (S207: No), the read level correction operation for the target correction unit U ends. The processing when the error correction fails is not limited to this.

When the error correction is successful (S207: Yes), the CPU 11 acquires the FBC from the ECC circuit 15 and records the acquired FBC in the FBC information 304 (S208).

Subsequently, the CPU 11 determines whether the value of the loop index i is equal to N (S209). When the value of the loop index i is not equal to N (S209: No), the CPU 11 increments the value of the loop index i by 1 (S210), and the control transitions to S203.

When the value of the loop index i is equal to N (S209: Yes), that is, when the processing in S203 to S208 is executed for all the storage areas in the target correction unit U, the FBC vector Y for the target correction unit U is completed in the FBC information 304. The CPU 11 multiplies the pseudo-inverse matrix A corresponding to the page type of the target correction unit by the FBC vector Y (S211). In S211, the CPU 11 acquires the coefficient vector β.

The CPU 11 calculates the correction amount Δ of the read level by using the coefficients in the read level dependent terms of the coefficient vector β (S212). The minimum unit of change in the read level is a DAC. Therefore, in S212, the CPU 11 calculates the correction amount Δ discretized in the DAC unit.

The CPU 11 updates the set value of the read level for the correction unit U of the target recorded in the read level information 301 by using the correction amount Δ obtained by the calculation (S213). That is, the CPU 11 calculates a new set value of the read level by adding the correction amount Δ to the set value of the read level, and records the new set value of the read level obtained by the addition in the read level information 301 in an overwrite format. Thereby, the read level correction operation for the target correction unit U ends.

The shift read in S206 of the series of operations illustrated in FIG. 17 may be executed by a sequential read method. For example, when the correction units Ul1 to Ul8 (refer to FIG. 9), the correction units Um1 to Um8 (refer to FIG. 11), and the correction units Uu1 to Uu8 (refer to FIG. 14) are configured, and a series of operations illustrated in FIG. 17 are executed for each of the correction units Ul1 to Ul8, Um1 to Um8, and Uu1 to Uu8, the memory controller 10 can execute the shift read in S206 for each storage area in the order illustrated in FIG. 6. As a result, data can be read from all the correction units U in a short time, and the read level correction operation for all the correction units Ul1 to Ul8, Um1 to Um8, and Uu1 to Uu8 can be completed in a short time.

The trigger of the series of operations illustrated in FIG. 17 is not limited to a specific trigger. In an example, when the target correction unit is in the address range for which the read is requested by the read command received from the host 2, the memory controller 10 can execute the read level correction operation using the sequential read method in parallel with the execution of the read requested by the host 2. The read command includes a logical address range representing a position of the read target data. The memory controller 10, for example, in the CPU 11 (or hardware that assists in that processing), specifies the physical address range, which is a read target, by converting each position within the logical address range into a physical address including the chip number, block number, WL number, SU number, and page type of the memory chip CP. The determination of whether the target correction unit is in the physical address range of the read target can be executed by, for example, the CPU 11 (or hardware that assists the processing of the CPU 11).

In another example, the memory controller 10 may execute the series of operations illustrated in FIG. 17 during a period when the memory controller 10 is not executing processing in response to a command from the host 2 as background processing independent of the processing in response to a command from the host 2. In addition, in the background processing, the memory controller 10 may execute a series of operations illustrated in FIG. 17 by using a sequential read method.

In still another example, when the memory controller 10 performs a read by the sequential read method in response to a read command received from the host 2, the memory controller 10 may execute the series of operations illustrated in FIG. 17 when performing a read by the sequential read method in response to the read command. Specifically, the memory controller 10 determines whether the read by the sequential read method can be executed based on a physical address range of a read target specified in response to the read command. When it is determined that the sequential read method can be executed, the memory controller 10 executes a series of operations illustrated in FIG. 17 when reading data requested to be read from the host 2 by the sequential read method.

In the above description, the NAND memory 20 is an example of a non-volatile first memory. One of the lower page, the middle page, and the upper page is an example of a first page. A page different from the first page among the lower page, the middle page, and the upper page is an example of a second page. The read level used to determine the data on the first page is an example of a first read level. The read level used to determine the data on the second page is an example of a second read level.

For example, when the first page is a lower page, the read level VA and the read level VE correspond to a first read level. When the second page is a middle page, the read level VB, the read level VD, and the read level VF correspond to a second read level.

The read level information 301 is an example of first information. The design matrix information 302 is an example of second information. The pseudo-inverse matrix information 303 is an example of third information. The RAM 30 is an example of a second memory configured to store the first information, the second information, and the third information. The second memory may be configured with a plurality of memory devices, and the first information, the second information, and the third information may be stored in a distributed manner in the plurality of memory devices.

In Formula (2) or Formula (9), the interaction term and the word line offset dependent term are examples of a position dependent term.

According to the first embodiment, the memory controller 10 reads data from each of the storage areas constituting the target correction unit U by using the value of the first read level obtained by changing the set value of the first read level corresponding to the first page which is a certain page type of the target correction unit U in a change pattern defined by each different row of the design matrix D (an example of the first design matrix) corresponding to the first page (for example, refer to S203 to S205 in the loop processing of S203 to S210 in FIG. 17). The memory controller 10 calculates the coefficient vector β based on the FBC of the data read from each of the storage areas configuring the target correction unit U and the pseudo-inverse matrix A (an example of the first pseudo-inverse matrix) corresponding to the first page (for example, refer to S211 in FIG. 17). The memory controller 10 calculates the correction amount of the first read level for reducing the number of error bits generated when the read operation is performed for the target correction unit U, based on the calculated value of the coefficient vector β and the model formula (for example, refer to S212 in FIG. 17). The memory controller 10 updates the set value of the first read level based on the correction amount (for example, refer to S213 in FIG. 17).

Therefore, the required capacity of the buffer for the read level correction operation can be significantly reduced as compared with Comparative Example 1 and Comparative Example 2. That is, it is possible to appropriately correct the read level value.

In addition, since the capacity of the buffer required per one correction unit U is significantly smaller than that in the read level correction operation according to the comparative example, it is possible to use sequential read method while reducing the capacity of the buffer required as compared to that in Comparative Example 1. When the sequential read method is used, the read level correction operation for a large number of correction units U can be completed in a short time. That is, the read level value can be appropriately corrected in that the read level correction operation can be completed in a short time.

In the first embodiment, the read level correction operation is executed for each page type. The memory controller 10 reads data from each of the storage areas constituting the target correction unit U by using the value of the second read level obtained by changing the set value of the second read level corresponding to the second page which is a page type different from the first page of the target correction unit U in a change pattern defined by each different row of the design matrix D (an example of the second design matrix) corresponding to the second page (for example, refer to S203 to S205 in the loop processing of S203 to S210 in FIG. 17). The memory controller 10 calculates the coefficient vector β based on the FBC of the data read from each of the storage areas configuring the target correction unit U and the pseudo-inverse matrix A (an example of the second pseudo-inverse matrix) corresponding to the second page (for example, refer to S211 in FIG. 17). The memory controller 10 calculates the correction amount of the second read level for reducing the number of error bits generated when the read operation is performed for the target correction unit U, based on the calculated value of the coefficient vector β and the model formula (for example, refer to S212 in FIG. 17). The memory controller 10 updates the set value of the second read level based on the correction amount (for example, refer to S213 in FIG. 17).

Further, according to the first embodiment, the memory controller 10 calculates the correction amount by using the coefficients in the read level dependent term of the coefficient vector β obtained by calculation. This calculation method is equivalent to calculating the correction amount by substituting 0 as the word line offset into the model formula. That is, in the first embodiment, the memory controller 10 uses the correction amount obtained by substituting the value of one word line offset in the storage area configuring the correction unit U into the model formula, for the correction of the read level for the correction unit U.

In this manner, when the read level for the correction unit U is collectively corrected by using the correction amount obtained by substituting the value of one word line offset in the storage area configuring the correction unit U into the model formula, the set value of the read level may be managed for each correction unit U, and the size of the read level information 301 can be reduced.

### Second Embodiment

The calculation of the correction amount by one operation illustrated in FIG. 17 may have an upper limit on the positive side of the correction amount and a lower limit on the negative side of the correction amount. Specifically, for example, the CPU 11 may limit the correction amount to a range from −1 DAC to +1 DAC. In this manner, the correction amount is limited to a predetermined range, and thus, it is possible to prevent the read level from being greatly changed in one operation.

In addition, the sign of the coefficient β of the second order term of the read level dependent term may be negative due to some cause. When the sign of the coefficient β of the second order term of the read level dependent term is negative, the read level dependent term does not have a local minimum point, and thus the read level value at which the read level dependent term takes a minimum value is not determined. By providing an upper limit and a lower limit for the correction amount, it is possible to determine a read level value at which the read level dependent term takes a minimum value for convenience, even when a sign of the coefficient β of the second order term of the read level dependent term is negative.

The correction is performed in units of DACs. When the correction amount is limited to a range from −1 DAC to +1 DAC, the candidates for the correction amount are limited to three types of −1 DAC, 0, and +1 DAC. Therefore, the CPU 11 may simply substitute −1, 0, and +1 for x in Formula (7), Formula (8) and the like to determine a value of x that minimizes a value of y as a correction amount.

### Third Embodiment

According to the first embodiment, one pair of the design matrix D and the pseudo-inverse matrix A is prepared for one page type. A plurality of pairs of the design matrix D and the pseudo-inverse matrix A may be prepared for one page type.

For example, a plurality of pairs of the design matrix D and the pseudo-inverse matrix A are prepared for a certain page type. More specifically, the first design matrix D and the third design matrix D for the same page type are recorded in the design matrix information 302. Similar to the first design matrix D, the third design matrix D is a matrix that defines a change pattern of the first read level, and has the same number of rows as the number of storage areas configuring the correction unit U. The first pseudo-inverse matrix A and the third pseudo-inverse matrix A are recorded in the pseudo-inverse matrix information 303. The third pseudo-inverse matrix A is a pseudo-inverse matrix of a third model matrix X. The third model matrix X is a matrix having the same number of rows as the number of storage areas constituting the correction unit U, and is a model matrix corresponding to the third design matrix D and the same model formula as the first design matrix D. The memory controller 10 uses the third design matrix D and the third pseudo-inverse matrix A when the memory controller 10 executes the read level correction operation again for the correction unit U after executing the read level correction operation using the first design matrix D and the first pseudo-inverse matrix A for the correction unit U.

In this manner, when a plurality of read level correction operations are executed for one correction unit U, the memory controller 10 switches a pair of the design matrix D and the pseudo-inverse matrix A to be used.

For example, during the operation of the memory system 1, the memory system 1 may be in a situation where the design matrix D and the pseudo-inverse matrix A are not suitable for the correction in which the set value of the read level is brought closer to the optimal read level. In such a case, the memory controller 10 can perform correction to bring the set value of the read level closer to the optimal read level by switching the design matrix D and the pseudo-inverse matrix A used in the read level correction operation.

When a plurality of pairs of the design matrix D and the pseudo-inverse matrix A are prepared for the same page type, one of the two design matrices D for the same page type may be equivalent to a matrix obtained by changing the row arrangement order with respect to the other of the two design matrices.

### Fourth Embodiment

In the first embodiment, the memory controller 10 calculates the correction amount of the read level by using the coefficients in the read level dependent term of the estimated coefficient vector β. The calculation method of the correction amount of the read level is not limited to this. The memory controller 10 may correct the read level in units of storage areas.

For example, the memory controller 10 calculates the correction amount for each storage area constituting the correction unit U based on a model formula in which the value of the word line offset of each storage area constituting the correction unit U is substituted into the position dependent term. The memory controller 10 corrects the set value of the read level for each of the storage areas constituting the correction unit U, based on the correction amount calculated for each of the storage areas constituting the correction unit U.

Therefore, it is possible to bring the read level with high accuracy to be closer to the optimal read level for each storage area constituting the correction unit U.

In addition, the memory controller 10 may calculate a correction amount for each storage area constituting the correction unit U based on a model formula in which a value of the word line offset of each storage area constituting the correction unit U is substituted into the position dependent term, and then calculate an average value of the correction amounts calculated for all storage areas constituting the correction unit U, and use the average value to correct the set value of the read level for the correction unit U.

Therefore, as in the first embodiment, the set value of the read level may be managed for each correction unit U, and the size of the read level information 301 can be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory system comprising:
a non-volatile first memory including a plurality of word lines and a plurality of memory cell groups, each of the plurality of memory cell groups connected to a corresponding one of the plurality of word lines, including a first storage area from which data is read using a first read level, and a second storage area from which data is read using a second read level;
a second memory configured to store first information with a set value of the first read level being recorded, second information with a first design matrix having N rows that defines change patterns of the first read level being recorded, and third information with a first model matrix being recorded, the first model matrix having N rows and corresponding to the first design matrix and a first model formula, and the first model formula having the first read level as an explanatory variable, the number of error bits as an objective variable, a position dependent term that is a term that depends on a position in N of the memory cell groups, and a plurality of first coefficients, wherein N is an integer equal to or greater than 2; and
a memory controller configured to
read data from the first storage area of each of the N memory cell groups based on changing the set value of the first read level in the change pattern defined by each different row of the first design matrix;
calculate the plurality of first coefficients based on the number of error bits in the data read from the first storage area of each of the N memory cell groups and the first model matrix;
calculate a correction amount of the set value of the first read level for reducing the number of error bits generated when performing a read operation for the first storage area of the N memory cell groups based on calculated values of the plurality of first coefficients and the first model formula; and
update the set value of the first read level recorded in the first information based on the correction amount.

2. The memory system according to claim 1, wherein
a set value of the second read level is recorded in the first information,
a second design matrix having N rows that define change patterns of the second read level is recorded in the second information,
a second model matrix is recorded in the third information, has N rows, and corresponds to the second design matrix and a second model formula,
the second model formula has the second read level as an explanatory variable, the number of error bits as an objective variable, the position dependent term, and a plurality of second coefficients, and
the memory controller is further configured to:
read data from the second storage area of each of the N memory cell groups based on changing the set value of the second read level in the change pattern defined by each different row of the second design matrix;
calculate the plurality of second coefficients based on the number of error bits in the data read from the second storage area of each of the N memory cell groups and the second model matrix;
calculate a correction amount of the set value of the second read level for reducing the number of error bits generated when performing a read operation for the second storage area of the N memory cell groups based on calculated values of the plurality of second coefficients and the second model formula; and
update the set value of the second read level recorded in the first information based on the correction amount of the set value of the second read level.

3. The memory system according to claim 1, wherein
a third design matrix, different from the first design matrix, has N rows that defines the change pattern of the first read level is recorded in the second information,
a third model matrix is recorded in the third information, has N rows, and corresponds to the third design matrix and the first model formula, and
the memory controller is further configured to update the set value of the first read level using the first design matrix and the first model matrix, and update the set value of the first read level using the third design matrix and the third model matrix.

4. The memory system according to claim 3, wherein
the third design matrix is equivalent to a matrix obtained by changing an arrangement order of rows with respect to the first design matrix.

5. The memory system according to claim 1, wherein
the memory controller is further configured to calculate the correction amount of the set value of the first read level based on the first model formula in which a value representing a position of one memory cell group among the N memory cell groups is substituted into the position dependent term.

6. The memory system according to claim 1, wherein
the memory controller is further configured to calculate the correction amount of the set value of the first read level for each of the N memory cell groups based on the first model formula in which a value representing each position of the N memory cell groups is substituted into the position dependent term.

7. The memory system according to claim 6, wherein
the memory controller is further configured to:
calculate an average value of the correction amount of the set value of the first read level calculated for each of the N memory cell groups; and
update the set value of the first read level by using the average value.

8. A method for controlling a non-volatile memory including a plurality of word lines and a plurality of memory cell groups, each of the plurality of memory cell groups connected to a corresponding one of the plurality of word lines, including a first storage area from which data is read using a first read level, and a second storage area from which data is read using a second read level, the method comprising:
reading data from the first storage area of each of N of the plurality of memory cell groups based on changing a set value of the first read level in a change pattern defined by each different row of a first design matrix with N rows that define the change pattern of the first read level, wherein N is an integer is equal to or greater than 2;
calculating a plurality of first coefficients based on the number of error bits in the data read from the first storage area of each of the N memory cell groups and a first model matrix having N rows and corresponding to the first design matrix and a first model formula, and the first model formula is a formula having the first read level as an explanatory variable, the number of error bits as an objective variable, a position dependent term that is a term that depends on a position in the N memory cell groups among the plurality of memory cell groups, and the plurality of first coefficients;
calculating a correction amount of the set value of the first read level for reducing the number of error bits generated when performing a read operation for the first storage area of the N memory cell groups based on calculated values of the plurality of first coefficients and the first model formula; and
updating the set value of the first read level based on the correction amount.

9. The memory system according to claim 1, wherein the non-volatile first memory includes a NAND flash memory.

10. The memory system according to claim 1, wherein the memory controller is operatively coupled to a host through an interface circuit according serial advanced technology attachment (SATA) standard, a serial attached SCSI (SAS) standard, or a peripheral components interconnect (PCI) Express™ standard.

11. The memory system according to claim 1, wherein the memory controller is configured as a system-on-a-chip.

12. The method according to claim 8, wherein the non-volatile memory includes a NAND flash memory.
